(19) United States
(12) Patent Application Publication
(10) Pub. No.: US 2010/0223514 A1
(43) Pub. Date: Sep. 2, 2010

(54) SEMICONDUCTOR MEMORY DEVICE

(75) Inventors: Masaru NARA, Tokyo (JP); Hiroshi Ichikawa, Tokyo (JP)

Correspondence Address: MCDERMOTT WILL & EMERY LLP, 600 13TH STREET, N.W., WASHINGTON, DC, 20005-3096, US

(73) Assignee: ELPIDA MEMORY, INC.

(21) Appl. No.: 12/712,529

(22) Filed: Feb. 25, 2010

(30) Foreign Application Priority Data
Feb. 27, 2009 (JP) 2009-045833

(51) Int. Cl. G11C 29/04; G06F 11/22

(52) U.S. Cl. 714/719; 714/E11.145

(57) ABSTRACT

A semiconductor memory device includes a determination circuit that generates a determination signal by determining an error of read data read out from a memory cell array, and an I/O circuit that outputs the read data or the determination signal to outside via a data input/output terminal. The I/O circuit outputs the read data to outside at a first timing in a normal: operation mode, and in a test mode, outputs the determination signal to outside at a second timing later than the first timing. A difference between the first timing and the second timing is an integer times of a cycle of a clock signal. In this way, the determination signal can be correctly output in the test mode, because an output timing of the determination signal is controlled to be delayed from an output timing of the read data within the device.

### BACKGROUND OF THE INVENTION

1. Field of the Invention

The present invention relates to a semiconductor memory device, and more particularly relates to a semiconductor memory device having a determination circuit that determines an error of read data in a test mode.

2. Description of Related Art

Semiconductor memory devices as represented by DRAM (Dynamic Random Access Memory) are shipped after passing various operation tests in a manufacturing stage. Many operation tests are performed in parallel to plural semiconductor memory devices. Therefore, semiconductor memory devices having a larger number of pins have a smaller number of chips that can be tested at the same time.

To solve the above problem, a semiconductor memory device having a determination circuit capable of performing a so-called parallel test has been known (see Japanese Patent Application Laid-open No. 2000-11695). A parallel test is a test of determining whether an error is included in plural pieces of read data to be output in parallel from plural I/O terminals, and the result of the test is output from one I/O terminal. With this arrangement, only one I/O terminal is sufficient as a terminal to be connected to a tester, even when there are a large number of I/O terminals. Therefore, it is possible to increase the number of chips capable of being tested in parallel.

However, because the parallel test involves a determining operation performed by a determination circuit, a timing of a determination signal reaching an output circuit in the parallel test is delayed, as compared with a timing of read data reaching an output circuit in a normal operation. Meanwhile, in the main, the semiconductor memory devices in recent years operate synchronously with a clock signal, and an output circuit of this type of semiconductor memory device operates synchronously with a clock signal. Therefore, when a determination signal reaches with a delay, the output circuit cannot output a determination signal to outside.

The delay of the determination signal to the output circuit in the determining operation can be cancelled when there is a sufficient operation margin in a normal operation. Therefore, the output circuit can output a determination signal at the same timing as an output timing of read data. However, when the frequency of a clock signal becomes high, the operation margin in the normal operation becomes small. Consequently, the delay of the determination signal to the output circuit in the determining operation cannot be cancelled, and the determination signal cannot be output.

The above problems commonly occur when performing any determining operation to read data within a semiconductor memory device, not only when performing a parallel test.

### SUMMARY

In one embodiment, there is provided a semiconductor memory device that includes: a memory cell array; a determination circuit that generates a determination signal by determining an error of read data read out from the memory cell array; and an output circuit that operates synchronously with a clock signal and outputs the read data or the determination signal to outside via an output terminal, wherein the output circuit outputs, in a normal operation mode, the read data to outside at a first timing after a read command is issued, and in a test mode, outputs the determination signal to outside at a second timing later than the first timing after the read command is issued, and a difference between the first timing and the second timing is an integer times of a cycle of the clock signal.

In another embodiment, there is provided a semiconductor memory device that includes: a memory cell array; a determination circuit that generates a determination signal by determining an error of read data readout from the memory cell array; an output circuit that outputs the read data or the determination signal to outside via an output terminal; and a latency control circuit that generates a read timing signal to control an operation timing of the output circuit, wherein the latency control circuit generates, in a normal operation mode, the read timing signal at a first timing after a read command is issued, and in a test mode, generates the read timing signal at a second timing later than the first timing after the read command is issued.

According to the present invention, a timing control is performed within the semiconductor memory device to delay an output timing of a determination signal from an output timing of read data, instead of canceling the delay of a determination signal to the output circuit in the determining operation. Therefore, regardless of the size of the operation margin in a normal operation, the determination signal can be correctly output in the test mode.

### DETAILED DESCRIPTION OF THE EMBODIMENTS

The above features and advantages of the present invention will be more apparent from the following description of certain preferred embodiments taken in conjunction with the accompanying drawings, in which:

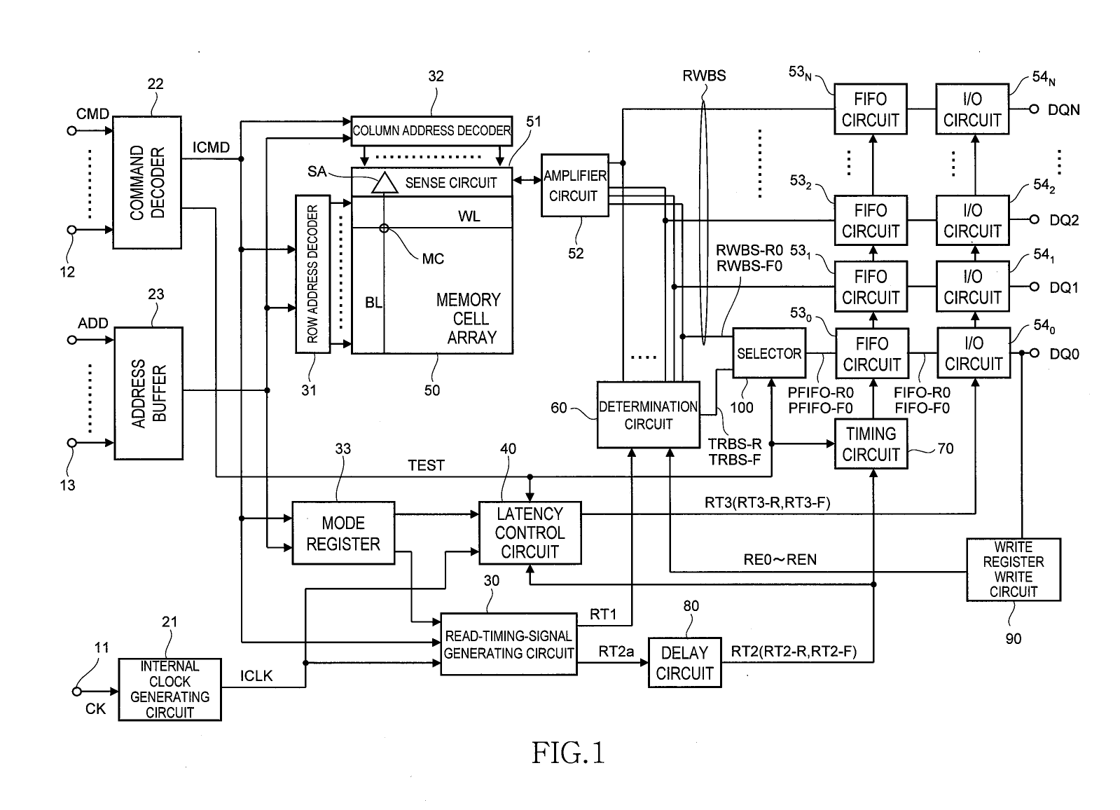

FIG. 1 is a block diagram showing an entire configuration of a semiconductor memory device according to an embodiment of the present invention;

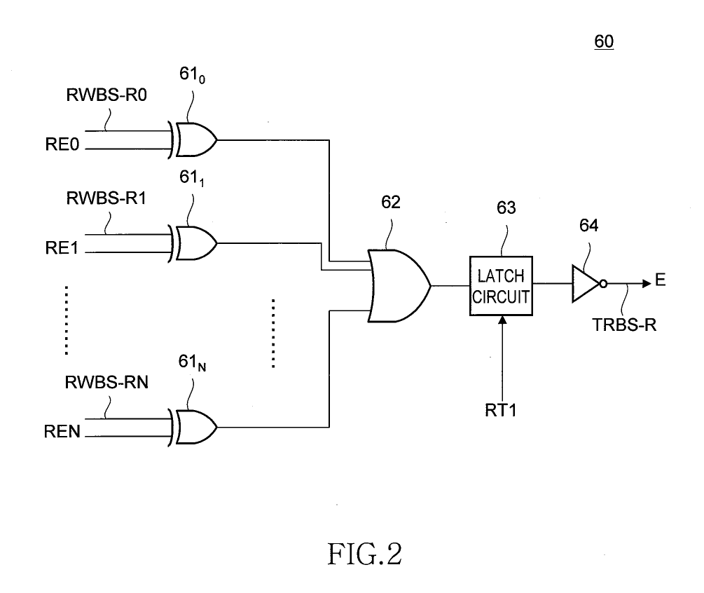

FIG. 2 is a circuit diagram of the determination circuit 60;

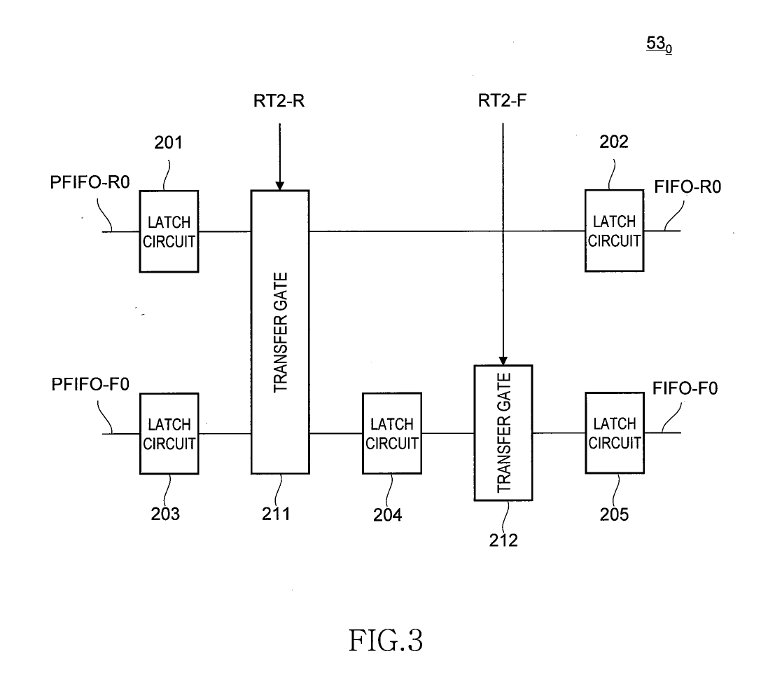

FIG. 3 is a circuit diagram of the FIFO circuit 53₀;

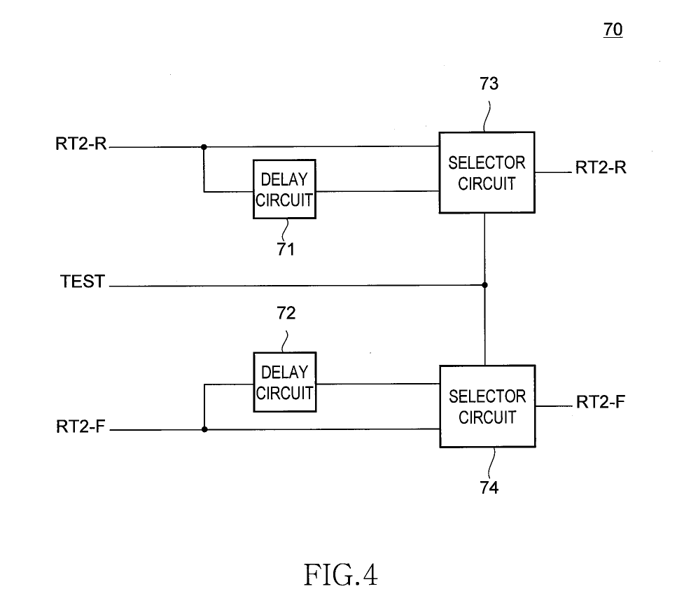

FIG. 4 is a circuit diagram of the timing circuit 70;

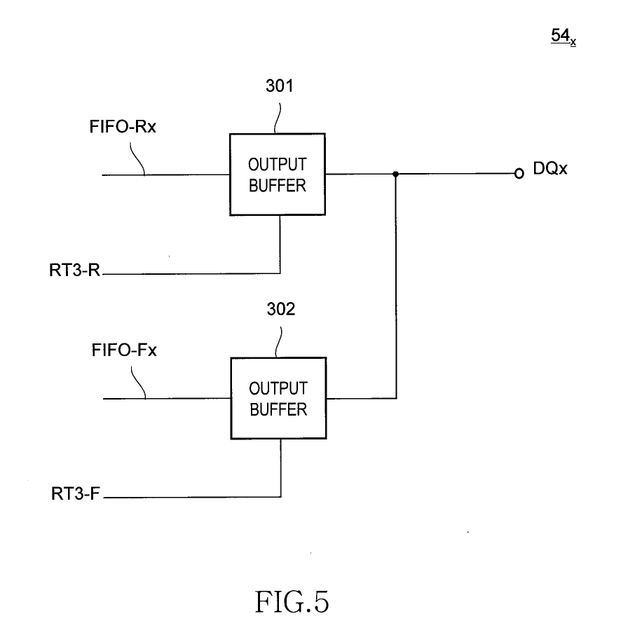

FIG. 5 is a circuit diagram of an I/O circuit 54ₓ;

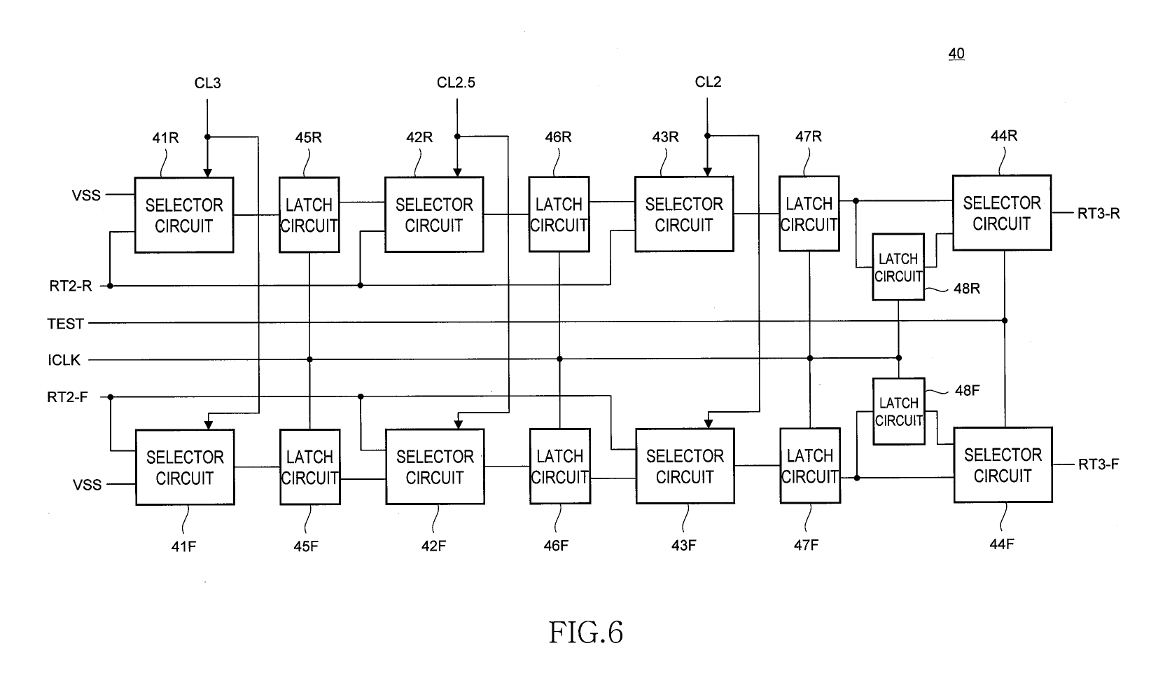

FIG. 6 is a circuit diagram of the latency control circuit 4;

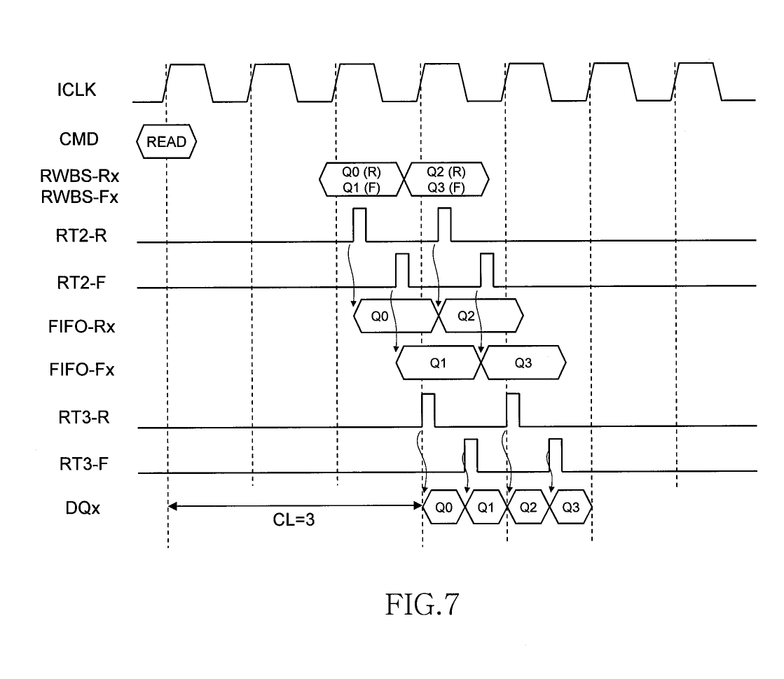

FIG. 7 is a timing diagram showing an operation of the semiconductor memory device in the normal operation mode; and

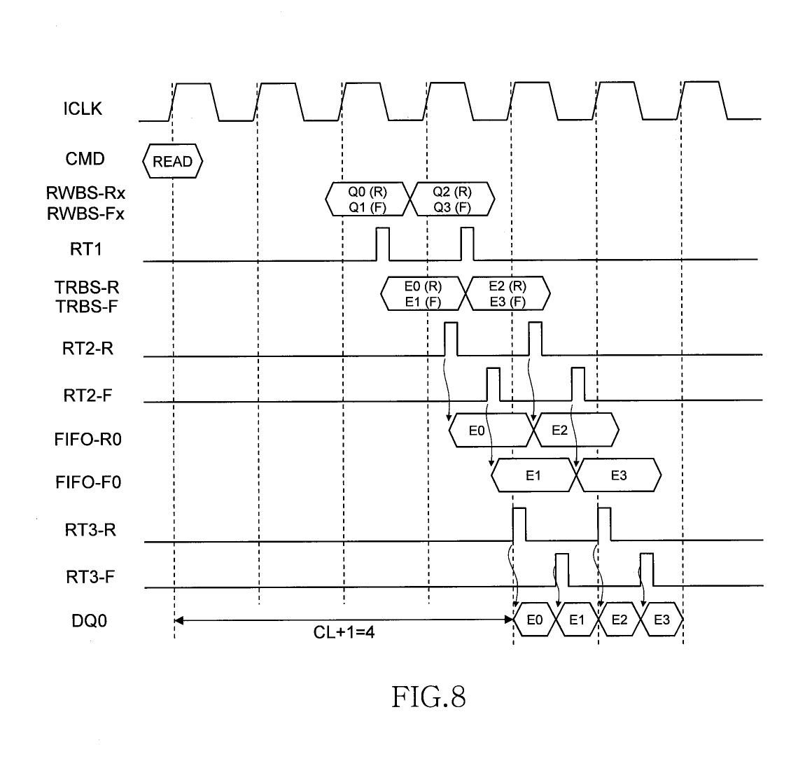

FIG. 8 is a timing diagram showing an operation of the semiconductor memory device in the test mode.

### DETAILED DESCRIPTION OF THE EMBODIMENTS

Preferred embodiments of the present invention will be explained below in detail with reference to the accompanying drawings.

FIG. 1 is a block diagram showing an entire configuration of a semiconductor memory device according to an embodiment of the present invention.

The semiconductor memory device according to the present embodiment is a DDR (Double Data Rate) synchronous DRAM, and includes a clock terminal 11, a command terminal 12, an address terminal 13, and data input/output terminals DQ0 to DQN, as external terminals. While the semiconductor memory device also includes other terminals such as a power source terminal, these are not shown in FIG. 1.

The clock terminal 11 receives an external clock signal CK, and supplies the received external clock signal CK to an internal clock generating circuit 21. The internal clock generating circuit 21 generates an internal clock signal ICLK based on the external clock signal CK. The internal clock signal ICLK is supplied to a read-timing-signal generating circuit 30. The internal clock signal ICLK is also supplied to various other internal circuits, which are not shown in FIG. 1.

The command terminal 12 receives input of command signals CMD such as a row address strobe signal and a column address strobe signal. These command signals CMD are supplied to a command decoder 22. The command decoder 22 is a circuit that generates various internal commands ICMD and a test mode signal TEST, by holding, decoding, and counting command signals. Generated internal commands ICMD are supplied to the read-timing-signal generating circuit 30, a row address decoder 31, a column address decoder 32, and a mode register 33. The test mode signal TEST is supplied to a latency control circuit 40.

The address terminal 13 receives an address signal ADD, and supplies this address signal ADD to the address buffer 23. The address buffer 23 latches the address signal ADD synchronously with the internal clock ICLK. Out of the address signal ADD latched by the address buffer 23, a row address is supplied to the row address decoder 31, and a column address is supplied to the column address decoder 32. When in a mode register set (when the command signal CMD shows a mode register set), the address signal ADD is supplied to the mode register 33, thereby updating contents of the mode register 33. A latency (CL) and a burst length (BL) are set to the mode register 33, thereby also performing entry to the test mode.

The row address decoder 31 is a circuit that selects any one of word lines WL included in a memory cell array 50. Plural word lines WL and plural bit lines BL cross each other within the memory cell array 50. Memory cells MC are arranged at intersections of these lines. FIG. 1 shows only one word line WL, one bit line BL, and one memory cell MC. The bit lines BL are connected to corresponding sense amplifiers SA within the sense circuit 51.

The column address decoder 32 is a circuit that selects any one of sense amplifiers SA. A sense amplifier SA selected by the column address decoder 32 is connected to an amplifier circuit 52. The amplifier circuit 52 further amplifies read data amplified by the sense amplifier SA, and supplies the further-amplified read data to FIFO circuits 53₀ to 53_{N} and a determination circuit 60.

The data input/output terminals (output terminals) DQ0 to DQN output read data and input write data, and are connected to corresponding I/O circuits (output circuits) 54₀ to 54_{N}, respectively. The I/O circuits 54₀ to 54_{N} are connected to corresponding FIFO circuits 53₀ to 53_{N}, respectively. In a read operation, the I/O circuits 54₀ to 54_{N} output read data supplied from the FIFO circuits 53₀ to 53_{N}, via corresponding data input/output terminals DQ0 to DQN, respectively. Therefore, the semiconductor memory device according to the present embodiment can input and output N+1 bit data in parallel. Although a value of N+1 is not particularly limited, this can be 128 or 256 when a multi-bit semiconductor memory is used.

A timing circuit 70 controls an operation of the FIFO circuits 53₀ to 53_{N}. As shown in FIG. 1, the test mode signal TEST and a read timing signal RT2 are supplied to the timing circuit 70. A circuit configuration of the timing circuit 70 is described later. The read timing signal RT2 is obtained by delaying a read timing signal RT2a output from the read-timing-signal generating circuit 30 by a delay circuit 80. The read timing signal RT2 includes read timing signals RT2-R and RT2-F of which phases are different from each other by a half cycle of the internal clock signal ICLK.

Operations of the I/O circuits 54₀ to 54_{N} are controlled by a read timing signal RT3. The read timing signal RT3 is supplied by the latency control circuit 40. The read timing signal RT3 includes read timing signals RT3-R and RT3-F of which phases are different from each other by a half cycle of the internal clock signal ICLK.

Two read/write buses RWBS are connected per one I/O between the amplifier circuit 52 and the FIFO circuits 53₀ to 53_{N}, respectively. In the present embodiment, 2×(N+1) read/write buses RWBS are provided, because the number of I/O is N+1. Therefore, the total number of the read/write buses RWBS is 256 when N+1=128, and the total number of the read/write buses RWBS is 512 when N+1=256.

The amplifier circuit 52 simultaneously reads two-bit data per one I/O, and supplies the read data to a corresponding read/write bus RWBS. One of the two-bit data is to be output synchronously with a rising edge of a clock signal, and the other of the two-bit data is to be output synchronously with a falling edge of the clock signal. Therefore, the amplifier circuit 52 is connected to each of the FIFO circuits 53₀ to 53_{N} by two read/write buses RWBS. Specifically, the amplifier circuit 52 is connected to a FIFO circuit 53ₓ (x=0 to N) by two read/write buses RWBS-Rx and RWBS-Fx. However, FIG. 1 shows in one line this pair of read/write buses RWBS-Rx and RWBS-Fx, to facilitate the understanding of FIG. 1.

These read/write buses RWBS are connected to the determination circuit 60 as well as to the FIFO circuits 53₀ to 53_{N}. The determination circuit 60 performs a parallel test in the test mode.

FIG. 2 is a circuit diagram of the determination circuit 60. The determination circuit 60 includes two circuits of a circuit for the read/write bus RWBS-Rx (for rising) and a circuit for the read/write bus RWBS-Fx (for falling). Because these circuits have the same circuit configurations, FIG. 2 shows only the circuit for rising.

As shown in FIG. 2, the determination circuit 60 (the circuit for rising of the determination circuit 60) includes N+1 EOR (exclusive logical sum) circuits 61₀ to 61_{N}, and an OR (logical sum) circuit 62 that integrates outputs of the N+1 EOR circuits 61₀ to 61_{N}. Signals of corresponding read/write buses RWBS-R0 to RWBS-RN, and expected values RE0 to REN corresponding to these signals are input to the EOR circuits 61₀ to 61_{N}, respectively. The expected values RE0 to REN are signals supplied from a write register write circuit 90 shown in FIG. 1. The write register write circuit 90 temporarily holds write data serially supplied from the data input/output terminal DQ0 in the test mode, and supplies the write data to the determination circuit 60 as the expected values RE0 to REN. That is, the expected values RE0 to REN are write data corresponding to read data.

Therefore, when corresponding read data and write data all match each other, outputs of the EOR circuits 61₀ to 61_{N} all become low level. Consequently, an output of the OR circuit 62 also becomes low level. On the other hand, when even one of corresponding read data does not match write data, the output of the OR circuit 62 becomes high level, because the outputs of the EOR circuits 61₀ to 61_{N} include a high level output.

A latch circuit 63 latches the output of the OR circuit 62. An inverter 64 inverts the latched output, and outputs an inverted result to a determination signal bus TRBS-R as a determination signal E. The latch timing of the latch circuit 63 is controlled by a read timing signal RT1. The read-timing-signal generating circuit 30 shown in FIG. 1 generates the read timing signal RT1. The circuit for falling included in the determination circuit 60 outputs the determination signal E to a determination signal bus TRBS-F shown in FIG. 1.

As shown in FIG. 1, the determination signal buses TRBS-R and TRBS-F are connected to one input end of a selector 100. A pair of read/write buses RWBS-R0 and RWBS-F0 is connected to the other input end of the selector 100. The selector 100 connects one of these read/write buses to FIFO input buses PFIFO-R0 and PFIFO-F0. Specifically, when the test mode signal TEST is in an inactive state (in a normal operation mode), the read/write buses RWBS-R0 and RWBS-F0 are selected, and the selected read/write buses are connected to the FIFO input buses PFIFO-R0 and PFIFO-F0, respectively. On the other hand, when the test mode signal TEST is in an active state (in the test mode), the determination signal buses TRBS-R and TRBS-F are selected, and the selected determination signal buses are connected to the FIFO input buses PFIFO-R0 and PFIFO-F0, respectively.

The FIFO input buses PFIFO-R0 and PFIFO-F0 are connected to the FIFO circuit 53₀. Therefore, the FIFO circuit 53₀ receives read data supplied from the read/write buses RWBS-R0 and RWBS-F0 in the normal operation mode, and receives the determination signal E supplied from the determination signal buses TRBS-R and TRBS-F in the test mode. Other FIFO circuits 53₁ to 53_{N} are not connected to the determination circuit 60, but are directly connected to the amplifier circuit 52. That is, the determination signal E is not supplied to the other FIFO circuits 53₁ to 53_{N}.

FIG. 3 is a circuit diagram of the FIFO circuit 53₀.

As shown in FIG. 3, the FIFO circuit 53₀ includes latch circuits 201 and 202 connected between the FIFO input bus PFIFO-R0 and a FIFO output bus FIFO-R0, and a transfer gate 211 provided between the latch circuits 201 and 202. The transfer gate 211 is a circuit that passes data synchronously with the read timing signal RT2-R. Therefore, data output from the FIFO output bus FIFO-R0 is a signal synchronous with the read timing signal RT2-R.

The FIFO circuit 53₀ also includes latch circuits 203 to 205 connected between the FIFO input bus PFIFO-F0 and a FIFO output bus FIFO-F0, and a transfer gate 212 provided between the latch circuits 204 and 205. The transfer gate 211 is also present between the latch circuits 203 and 204. The transfer gate 212 is a circuit that passes data synchronously with the read timing signal RT2-F. Therefore, data output from the FIFO output bus FIFO-F0 is a signal synchronous with the read timing signal RT2-F.

Other FIFO circuits 53₁ to 53_{N} have circuit configurations identical to that of the FIFO circuit 53₀ shown in FIG. 3, except that the FIFO circuits 53₁ to 53_{N} are connected to read/write buses RWBS-R1 to RWBS-RN in stead of the FIFO input bus PFIFO-R0, and are connected to read/write buses RWBS-F1 to RWBS-FN in stead of the FIFO input bus PFIFO-F0.

The read timing signals RT2 (RT2-R and RT2-F) are supplied to the transfer gates 211 and 212 via the timing circuit 70.

FIG. 4 is a circuit diagram of the timing circuit 70.

As shown in FIG. 4, the timing circuit 70 includes delay circuits 71 and 72 that delay the read timing signals RT2-R and RT2-F, respectively, and selector circuits 73 and 74. The test mode signal TEST is supplied to the selector circuits 73 and 74. The read timing signals RT2-R and RT2-F not delayed are selected when the test mode signal TEST is in an inactive state (in the normal operation mode). On the other hand, the read timing signals RT2-R and RT2-F delayed by the delay circuits 71 and 72 are selected when the test mode signal TEST is in an active state (in the test mode). Therefore, when the test mode signal TEST is activated, the read timing signals RT2-R and RT2-F are supplied to the FIFO circuits 53₀ to 53_{N} at a delayed timing.

Delay times of the delay circuits 71 and 72 are preferably set slightly longer than the time required for the determination circuit 60 to perform a determining operation. With this arrangement, the determination signal E is supplied to the I/O circuit 54₀ at an optimum timing. The delay circuits 71 and 72 operate asynchronously with a clock signal, because the time required for the determining operation is not synchronous with the clock signal. Consequently, the delay times are designed to match the time required for the determining operation, regardless of the clock signal.

FIG. 5 is a circuit diagram of an I/O circuit 54ₓ.

As shown in FIG. 5, the I/O circuit 54ₓ includes an output buffer 301 provided between a FIFO output bus FIFO-Rx and a data input/output terminal DQx, and an output buffer 302 provided between a FIFO output bus FIFO-Fx and the data input/output terminal DQx. The I/O circuit 54ₓ also includes an input receiver and the like, which are not shown in the drawings.

The output buffer 301 is a circuit that outputs data on the FIFO output bus FIFO-Rx synchronously with the read timing signal RT3-R. Similarly, the output buffer 302 is a circuit that outputs data on the FIFO output bus FIFO-Fx synchronously with the read timing signal RT3-F.

As described above, the latency control circuit 40 supplies these read timing signals RT3-R and RT3-F.

FIG. 6 is a circuit diagram of the latency control circuit 40.

As shown in FIG. 6, the latency control circuit 40 includes serially-connected four selector circuits 41R to 44R, and latch circuits 45R to 47R provided between these selector circuits. An output of a preceding stage is input to one input end of each of the selector circuits 41R to 43R (a ground potential VSS is supplied to the selector circuit 41R at the first stage). The read timing signal RT2-R is supplied to the other input end of each selector circuit. Selection performed by the selector circuits 41R to 43R is determined by the latency (CL) set in the mode register 33.

In an example shown in FIG. 6, one of latency signals CL3, CL2.5, and CL2 that become an active level is supplied to each of the selector circuits 41R to 43R, based on the latency set in the mode register 33. A selector circuit to which an active latency signal is input selects the read timing signal RT2-R. On the other hand, a selector circuit to which an inactive latency signal is input selects an output of a preceding stage.

Each of the latch circuits 45R and 47R fetches an input signal synchronously with a rising edge of the internal clock signal ICLK. On the other hand, the latch circuit 46R fetches an input signal synchronously with a falling edge of the internal clock signal ICLK.

Further, a latch circuit 48R is provided between the latch circuit 47R and the selector circuit 44R. The latch circuit 48R fetches an input signal synchronously with a rising edge of the internal clock signal ICLK, and supplies an output signal to the selector circuit 44R. Selection performed by the selector circuit 44R is determined by the test mode signal TEST. The selector circuit 44R selects an output of the latch circuit 47R when the test mode signal TEST is in an inactive state (in the normal operation mode), and selects an output of the latch circuit 48R when the test mode signal TEST is in an active state (in the test mode). An output of the selector circuit 44R is used as the read timing signal RT3-R.

As shown in FIG. 6, the latency control circuit 40 further includes similar circuits (selector circuits 41F to 44F, latch circuits 45F to 48F) corresponding to the read timing signal RT2-F. Out of the circuits corresponding to the read timing signal RT2-F, the latch circuits 45F, 47F, and 48F fetch input signals synchronously with a falling edge of the internal clock signal ICLK. On the other hand, the latch circuit 46F fetches an input signal synchronously with a rising edge of the internal clock signal ICLK.

Based on the above configuration, the latency control circuit 40 generates and outputs the read timing signals RT3-R and RT3-F obtained by delaying the read timing signals RT2-R and RT2-F by a latency component, when the test mode signal TEST is in an inactive state (in the normal operation mode). On the other hand, when the test mode signal TEST is in an inactive state (in the test mode), the latency control circuit 40 generates and outputs the read timing signals RT3-R and RT3-F obtained by delaying the read timing signals RT2-R and RT2-F by “latency+one clock-cycle component”.

The configuration of the semiconductor memory device according to the present embodiment is as described above. An operation of the semiconductor memory device according to the embodiment is described next.

FIG. 7 is a timing diagram showing an operation of the semiconductor memory device in the normal operation mode. FIG. 7 shows an example of an operation when a value of a latency set in the mode register 33 is 3(CL=3) and when a burst length is 4(BL=4).

As shown in FIG. 7, read data Q0 and Q1 assigned by an input address are read out from the memory cell array 50 when a read command READ is issued in the normal operation mode. The read data Q0 and Q1 are supplied to the read/write buses RWBS-Rx and RWBS-Fx after two clock cycles. Read data Q2 and Q3 are read out next, and are supplied to the read/write buses RWBS-Rx and RWBS-Fx three clock cycles after the read command is issued.

In this example, the selector 100 selects the read/write buses RWBS-R0 and RWBS-F0 because the test mode signal TEST is in an inactive state. Therefore, the read data Q0 to Q3 supplied to the read/write buses RWBS-Rx and RWBS-Fx are directly supplied to the FIFO circuits 53₀ to 53_{N}.

The FIFO circuits 53₀ to 53_{N} parallel-serially exchanges two bit data synchronously with the read timing signals RT2-R and RT2-F alternately generated at every one-half cycle of the internal clock signal ICLK, and output serially-converted read data Q0 to Q3 to the I/O circuits 54₀ to 54_{N}. Because the burst length is 4 in this example, the read timing signals RT2-R and RT2-F are activated at four times in total. The I/O circuits 54₀ to 54_{N} output the read data Q0 to Q3 to the data input/output terminals DQ0 to DQN synchronously with the read timing signals RT3-R and RT3-F alternately generated at four times in total at every one-half cycle of the internal clock signal ICLK. The first read data Q0 is output three clock cycles (=CL) after a read command is issued.

As explained above, in the normal operation mode, the read data Q0 to Q3 are continuously output in parallel from N+1 data input/output terminals DQ0 to DQN. The first read data Q0 is output at the same timing as that of a latency set in the mode register 33.

FIG. 8 is a timing diagram showing an operation of the semiconductor memory device in the test mode. FIG. 8 also shows an example of an operation when a value of a latency set in the mode register 33 is 3(CL=3) and when a burst length is 4(BL=4).

As shown in FIG. 8, the read timing signal RT1 is activated in the test mode. The read timing signal RT1 is a latch signal of the latch circuit 63 included in the determination circuit 60. Accordingly, the latch circuit 63 fetches results of comparisons performed by the EOR circuits 61₀ to 61_{N} and the OR circuit 62, and supplies fetched results to the determination signal buses TRBS-R and TRBS-F as the determination signals E0 to E3.

The determination signals E0 to E3 are supplied to the determination signal buses TRBS-R and TRBS-F at a later timing, by the time required for a determining operation, later than a timing when the read data Q0 to Q3 are supplied to the read/write buses RWBS-R0 and RWBS-F0 in the normal operation mode. The read timing signals RT2-R and RT2-F delayed by the timing circuit 70 are supplied to the FIFO circuit 53₀, by taking this delay into account.

Furthermore, the read timing signals RT3-R and RT3-F delayed by one clock cycle by the latency control circuit 40 are supplied to the I/O circuit 54₀. The determination signals E0 to E3 are output from the data input/output terminal DQ0 synchronously with the supplied read timing signals. A first determination signal E0 is output at a timing of four clock cycles (=CL+1) after a read command is issued.

As explained above, in the test mode, the determination signals E0 to E3 are continuously output only from the data input/output terminal DQ0. In the present embodiment, the first read data Q0 is output at a timing of CL+1 greater than a latency set in the mode register 33.

As explained above, the semiconductor memory device according to the present embodiment automatically increases the latency within the device, when the device enters a test mode having a determining operation. Therefore, even a synchronous semiconductor memory device that inputs or outputs data synchronously with a clock signal can correctly output a result of a parallel test.

It is apparent that the present invention is not limited to the above embodiments, but may be modified and changed without departing from the scope and spirit of the invention.

In the above embodiment, an example that the determination circuit 60 performs a parallel test has been explained. However, the present invention is not limited to the case of performing a parallel test, and can be applied to all cases where a delay occurs due to performing of a certain determining operation to read data within a semiconductor memory device.

While a data input/output terminal and an I/O circuit are used in the above embodiment, a data input unit and a data output unit can be a separate terminal and a separate circuit. Therefore, at least an output terminal and an output circuit are sufficient for the data input/output terminal and the I/O circuit in the above embodiment.

What is claimed is:

1. A semiconductor device comprising:
a memory cell array;
a determination circuit that generates a determination signal by determining an error of read data readout from the memory cell array; and
an output circuit that outputs the read data or the determination signal to outside via an output terminal synchronously with a clock signal, wherein
the output circuit outputs the read data to outside at a first timing after a read command is issued in a normal operation mode, and outputs the determination signal to outside at a second timing later than the first timing after the read command is issued in a test mode, and
a difference between the first timing and the second timing is an integer times of a cycle of the clock signal.

2. The semiconductor device as claimed in claim 1, wherein
the output terminal is one of a plurality of output terminals,
the determination circuit generates the determination signal by determining whether plural pieces of read data to be output in parallel from the output terminals contain an error, and
the determination signal is output from any one of the output terminals.

3. The semiconductor device as claimed in claim 1, wherein the first timing is defined by a latency as an integer times of a cycle of the clock signal.

4. The semiconductor device as claimed in claim 3, further comprising a mode register set with the latency, and a latency control circuit that generates a first read timing signal to control an operation timing of the output circuit, wherein
the latency control circuit generates the first read timing signal based on a latency set in the mode register in the normal operation mode, and generates the first read timing signal based on a latency greater than the latency set in the mode register in the test mode.

5. The semiconductor device as claimed in claim 1, further comprising:
a FIFO circuit that supplies the read data or the determination signal to the output circuit; and
a timing circuit that generates a second read timing signal to control an output operation of the FIFO circuit, wherein
the timing circuit includes a delay circuit that delays the second read timing signal in the test mode, and
a delay time delayed by the delay circuit is longer than a time required for a determining operation performed by the determination circuit.

6. The semiconductor device as claimed in claim 5, wherein the delay circuit operates asynchronously with the clock signal.

7. A semiconductor device comprising:
a memory cell array;
a determination circuit that generates a determination signal by determining an error of read data read out from the memory cell array;
an output circuit that outputs the read data or the determination signal to outside via an output terminal; and
a latency control circuit that generates a read timing signal to control an operation timing of the output circuit, wherein
the latency control circuit generates the read timing signal at a first timing after a read command is issued in a normal operation mode, and generates the read timing signal at a second timing later than the first timing after the read command is issued in a test mode.
